(19) United States
(12) Patent Application Publication
(10) Pub. No.: US 2007/0285129 A1
(43) Pub. Date: Dec. 13, 2007

(54) SIGNAL TRANSMITTING CIRCUIT

(75) Inventor: MING-CHIH HSIEH, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/309,802

(22) Filed: Sep. 28, 2006

(30) Foreign Application Priority Data
Jun. 9, 2006 (CN) 200610061074.1

(51) Int. Cl. H03K 19/094

(52) U.S. Cl. 326/83

(57) ABSTRACT

An exemplary signal transmitting circuit includes a drive circuit, a receiving circuit, and a filter circuit coupled between the drive circuit and the receiving circuit. The filter circuit includes a first photocoupler having a first luminous element and a first optical receiving block, an anode of the first luminous element is coupled to a power source, a cathode of the first luminous element is coupled to the drive circuit, an anode of the first optical receiving block is coupled to the power source and the receiving circuit, and a cathode of the first optical receiving block is coupled to ground.

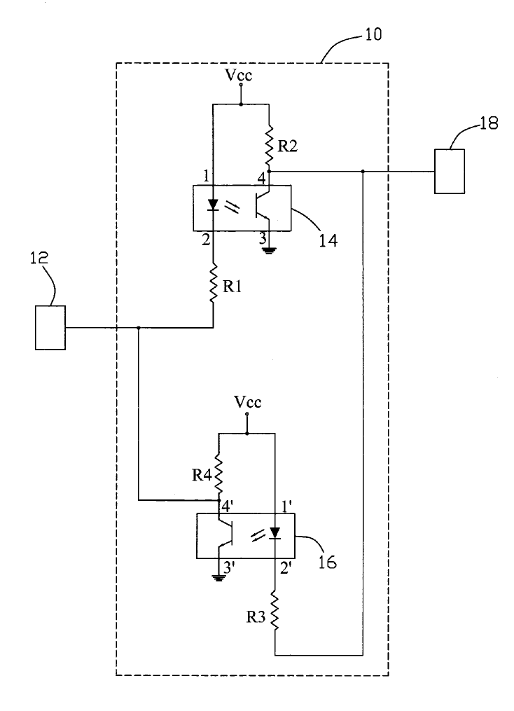

### FIELD OF THE INVENTION

The present invention relates to signal transmitting circuits, and particularly to a signal transmitting circuit having a filter circuit for filtering electromagnetic interference (EMI) in an electronic signal transmitted in the signal transmitting circuit.

### DESCRIPTION OF RELATED ART

Electromagnetic interference (EMI) is inherent to electrical components. EMI emissions from electronic assemblies that house electrical components or are connected to electronic devices that contain electrical components can adversely affect the operation of other electronic assemblies and devices. Thus, methods, systems, and apparatus for inhibiting EMI emissions of electronic assemblies are needed.

Conventionally, a drive circuit sends an electronic signal to a receiving circuit via a signal line without any filtering process. Therefore, EMI generated by the drive circuit will be transmitted to the receiving circuit.

What is needed, therefore, is a signal transmitting circuit which can filter EMI transmitted therein.

### SUMMARY OF THE INVENTION

An exemplary signal transmitting circuit includes a drive circuit, a receiving circuit, and a filter circuit coupled between the drive circuit and the receiving circuit. The filter circuit includes a first photocoupler having a first luminous element and a first optical receiving block, an anode of the first luminous element is coupled to a power source, a cathode of the first luminous element is coupled to the drive circuit, an anode of the first optical receiving block is coupled to the power source and the receiving circuit, and a cathode of the first optical receiving block is coupled to ground

Other advantages and novel features will become more apparent from the following detailed description when taken in conjunction with the accompanying drawing, in which:

### BRIEF DESCRIPTION OF THE DRAWINGS

The drawing is a circuit diagram of one embodiment of a signal transmitting circuit in accordance with the present invention.

### DETAILED DESCRIPTION OF THE INVENTION

Referring to the drawing, a signal transmitting circuit in accordance with a preferred embodiment of the present invention includes a drive circuit 12, a receiving circuit 18, and a filter circuit 10 coupled between the drive circuit 10 and the receiving circuit 18.

In this embodiment, the filter circuit 10 includes a first photocoupler 14 with a first luminous element like an LED and a first optical receiving block. An anode 1 of the first luminous element is coupled to a power source Vcc, and a cathode 2 of the first luminous element is coupled to the drive circuit 12 via a resistor R1. An anode 4 of the first optical receiving block is coupled to the receiving circuit 18, and the power source Vcc via a resistor R2, and a cathode 3 of the first optical receiving block is coupled to ground.

The filter circuit 10 further includes a second photocoupler 16 with a second luminous element and a second optical receiving block. An anode 1′ of the second luminous element is coupled to a power source Vcc, and a cathode 2′ of the second luminous element is coupled to the receiving circuit 18 via a resistor R3. An anode 4′ of the second optical receiving block is coupled to the drive circuit 12, and the power source Vcc via a resistor R4, and a cathode 3′ of the second optical receiving block is coupled to ground.

The power source Vcc is a 3.3 volts DC source for driving the first and the second photocouplers 14 and 16.

The drive circuit 12 sends an electrical signal to the receiving circuit 18 via the filter circuit 10, the first photocoupler 14 is actuated. When the drive circuit 12 sends a high-level voltage signal through the filter circuit 10, the first luminous element of the first photocoupler 14 is turned off and the first optical receiving block is turned off, therefore the receiving circuit 18 receives a high-level voltage from the power source Vcc. When the drive circuit 12 sends a low-level voltage signal through the filter circuit 10, the first luminous element is turned on and the first optical receiving block is turned on, therefore the receiving circuit 18 receives a low-level voltage from ground. Thus, any EMI from the signal sent by the drive circuit 12 will be cut off at the first photocoupler 14 and cannot be transmitted to the receiving circuit 18.

When the receiving circuit 18 sends a feedback electrical signal to the drive circuit 12 via the filter circuit 10, that is, when the receiving circuit 18 sends a high-level voltage signal through the filter circuit 10, the second luminous element of the second photocoupler 16 is turned off and the second optical receiving block is turned off, therefore the drive circuit 12 receives a high-level voltage from the power source Vcc. When the receiving circuit 18 sends a low-level voltage signal through the filter circuit 10, the second luminous element is turned on and the second optical receiving block is turned on, therefore the drive circuit 12 receives a low-level voltage from ground. Thus, any EMI from the signal will be cut off at the second photocoupler 16 and cannot be transmitted to the drive circuit 12.

The filter circuit 10 cuts off any EMI from electrical signals transmitted through it.

It is believed that the present invention and its advantages will be understood from the foregoing description, and it will be apparent that various changes may be made thereto without departing from the spirit and scope of the invention or sacrificing all of its material advantages, the example hereinbefore described merely being a preferred or exemplary embodiment of the invention.

What is claimed is:

1. A signal transmitting circuit comprising:
a drive circuit configured for sending an electrical signal;
a receiving circuit configured for receiving the electrical signal; and
a filter circuit coupled between the drive circuit and the receiving circuit for filtering electromagnetic interference from the electronic signal, the filter circuit including a first photocoupler having a first luminous element and a first optical receiving block, an anode of the first luminous element being coupled to a power source, a cathode of the first luminous element being coupled to the drive circuit, an anode of the first optical receiving block being coupled to the power source and the receiving circuit, and a cathode of the first optical receiving block being coupled to ground.

2. The signal transmitting circuit as claimed in claim 1, wherein a first resistor is coupled between the drive circuit and the cathode of the first luminous element, and a second resistor is coupled between the power source and the anode of the first optical receiving block.

3. The signal transmitting circuit as claimed in claim 1, wherein the filter circuit further comprises a second photocoupler having a second luminous element with an anode coupled to the power source and a cathode coupled to the receiving circuit, and a second optical receiving block with an anode coupled to the power source and the drive circuit, and a cathode coupled to ground.

4. The signal transmitting circuit as claimed in claim 3, wherein the power source is 3.3 volts.

5. The signal transmitting circuit as claimed in claim 3, wherein a third resistor is coupled between the receiving circuit and the cathode of the second luminous element, and a fourth resistor is coupled between the power source and the anode of the second optical receiving block.
